(19) United States
(12) Patent Application Publication
(10) Pub. No.: US 2019/0058447 A1
(43) Pub. Date: Feb. 21, 2019

(54) Behavioral Modeling Of Concurrent Multiband Power Amplifiers

(71) Applicant: King Fahd University of Petroleum and Minerals, Dhahran (SA)

(72) Inventors: Mohammed Abdalla Abdelrahim Ali, Dhahran (SA); Azzedine Mohamed Ali Zerguine, Dhahran (SA)

(73) Assignee: King Fahd University of Petroleum and Minerals, Dhahran (SA)

(21) Appl. No.: 15/998,390

(22) Filed: Aug. 15, 2018

Related U.S. Application Data
(60) Provisional application No. 62/545,633, filed on Aug. 15, 2017.

(51) Int. Cl. H03F 1/32; H03F 3/19; H03F 3/21

(52) U.S. Cl. CPC H03F 1/3205; H03F 3/19; H03F 3/21; H03F 2201/3215; H03F 2201/3224; H03F 2201/3233; H03F 1/3258

(57) ABSTRACT

An apparatus, method and computer readable medium are provided for behavioral modeling of a concurrent multiband amplifier. The apparatus includes a memory to store coefficients of a memory polynomial having summations over no more than four indices including memory order and nonlinearity order, and nonlinear terms confined to even powers, and a processor circuitry that executes a model of the multiband amplifier according to the memory polynomial. The coefficients are not indexed over is the memory order index which allows for a substantial reduction in number of coefficients and minimization of memory, but with high memory depth.

### CROSS REFERENCE TO RELATED APPLICATION

This application claims the benefit of priority under 35 U.S.C. § 119(e) to U.S. Provisional Patent Application No. 62/545,633 entitled “BEHAVIORAL MODELING OF CONCURRENT DUAL-BAND POWER AMPLIFIERS,” filed Aug. 15, 2017, the entire disclosure of which is incorporated herein by reference.

### BACKGROUND

### Field of the Invention

The present disclosure is directed to concurrent multiband power amplifiers. Specifically, the present is related to comprehensive different digital signal processing (DSP) solutions for distortion mitigation of different RF impairments in single-band, wideband and dual-band transmitters.

### Description of Related Art

Increasing demand for high data rates (around 1 Gbps) in wireless communication has led to the development and implementation of concurrent multiband transmission techniques. As used herein, a concurrent multiband signal is a signal that occupies multiple distinct frequency bands and contains no frequency components (apart from distortion) between adjacent frequency bands. Concurrent multi-band signals may be utilized in a multi-standard cellular communications system in which a base station transmits multiple signals for multiple different cellular communications protocols or standards simultaneously (or concurrently). Modern multiband or multi-standard transceivers typically rely on a single power amplifier (PA) to handle concurrent amplification of the multi-band signals. While such single PA implementations offer savings in cost and circuit size, concurrent multiband amplification through a common PA poses its own challenges.

A concurrent dual-band transmitter exhibits three types of intermodulation products at the output of the concurrent dual-band transmitter. The first type of intermodulation is referred to as in-band intermodulation and consists of intermodulation products around each carrier frequency (ω₁ and ω₂). In-band intermodulation arises from the intermodulation between signal elements within each band, which is similar to what is found in a single-band transmitter. The second type of intermodulation is referred to as cross-modulation and consists of intermodulation products that appear in the same frequency range as the in-band intermodulation but are the result of intermodulation between signal elements in both frequency bands (i.e., both the frequency band centered at ω₁ and the frequency band centered at ω₂). The third type of intermodulation products is referred to as out-of-band intermodulation and consists of intermodulation products between the two signals in both frequency bands that are located at Δω away from the lower and upper carrier frequencies. Out-of-band intermodulation may contain, for example, third-order intermodulation distortion. Accurate models of concurrent multiband power amplifiers must also simulate such intermodulation as well as gain compression and other behaviors of real world power amplifiers.

Interest in behavioral modeling of dual band power amplifiers has grown in recent years. Behavioral models are a set of mathematical expressions, and corresponding fitting coefficients, that represent the input-output relationship of a physical system. Behavioral models utilize only a minimal set of input information about device construction as compared to other types of models (e.g., physical models and equivalent circuit models). An ideal behavioral model for a power amplifier should be able to predict the nonlinear performance, such as gain compression and intermodulation distortion at different input power levels under various source/load conditions. Moreover, it should be able to predict the dynamic effects of amplifiers under modulated signal stimuli. The nonlinear artifacts of concurrent amplification impose challenges on behavioral model performance, which requires sampling rates of 5-7 times the signal bandwidth to include in-band and out-of-band IMDs.

Various models of concurrent multiband power amplifiers exist in the current state of the art, including “Concurrent Dual-Band Digital Predistortion using Lookup Tables with Variable Depths,” A. Kwan, et al., IEEE Power Amplifiers Wireless Radio Appl. Top. Conf. pp. 25-27, 2013, hereinafter “Kwan,” and “Advanced Digital Signal Processing Techniques for Linearization of Multi-band Transmitters,” F. Mayada, Ph.D. Dissertation, University of Calgary, 2014, hereinafter “Mayada.” These particular techniques are referred to herein for purposes of comparison with embodiments of the present disclosure. Research and development of behavioral models is ongoing.

### SUMMARY

An aspect is an apparatus for behavioral modeling of a concurrent multiband amplifier including a memory to store coefficients of a memory polynomial having summations over no more than four indices including memory order and nonlinearity order, and nonlinear terms confined to even powers, and a processor circuitry that executes a model of the multiband amplifier according to the memory polynomial.

An aspect is a method for behavioral modeling of a concurrent multiband amplifier including storing coefficients of a memory polynomial having summations over no more than four indices including memory order and nonlinearity order, and nonlinear terms confined to even powers, and executing a model of the multiband amplifier according to the memory polynomial.

An aspect is a non-transitory computer readable storage medium storing a program therein, which when executed by a computer performs a method for behavioral modeling of a concurrent multiband amplifier, the method including storing coefficients of a memory polynomial having summations over no more than four indices including memory order and nonlinearity order, and nonlinear terms confined to even powers, and executing a model of the multiband amplifier according to the memory polynomial

### BRIEF DESCRIPTION OF THE DRAWINGS

FIG. 1 is a block diagram of a circuit design and fabrication process in accordance with an exemplary aspect of the disclosure.

FIG. 2A is a schematic block diagram of a processing circuit in accordance with an exemplary aspect of the disclosure.

FIG. 2B is a schematic block diagram of a circuit design system in accordance with an exemplary aspect of the disclosure.

FIG. 3 is a schematic block diagram of a memory polynomial behavioral model in accordance with an exemplary aspect of the disclosure.

FIG. 4 is a schematic circuit diagram depicting an exemplary transmitter circuit design in accordance with an exemplary aspect of the disclosure.

FIG. 5 is a flow diagram of an example behavioral model design process that can be used in conjunction with embodiments of the present invention.

FIG. 6 is a flow diagram of a model identification process that can be used in conjunction with embodiments of the present invention

FIG. 7 is a schematic block diagram of an example system by which a behavioral model is configured for a specific power amplifier.

FIG. 8 is a graph illustrating performance characteristics (normalized mean square error (NMSE) in the low data band against the memory depth) of an embodiment.

FIG. 9 is a graph illustrating performance characteristics (NMSE in the high data band against the memory depth) of an embodiment.

FIG. 10 is a graph illustrating performance characteristics (NMSE in the low data band against the non-linearity order) of an embodiment.

FIG. 11 is a graph illustrating performance characteristics (NMSE in the high data band against the non-linearity order) of an embodiment.

FIG. 12 is a graph illustrating performance characteristics (frequency response in the low data band) of an embodiment.

FIG. 13 is a graph illustrating performance characteristics (frequency response in the high data band) of an embodiment.

FIG. 14 is an expanded view of the graph illustrated in FIG. 13.

FIG. 15 is graph illustrating performance characteristics (condition number in the low data band against the non-linearity order) of an embodiment.

FIG. 16 is graph illustrating performance characteristics (condition number in the high data band against the non-linearity order) of an embodiment.

### DETAILED DESCRIPTION

The present disclosure described through certain embodiments thereof, which are described in detail herein with reference to the accompanying drawings, wherein like reference numerals refer to like features throughout. It is to be understood that the term invention, when used herein, is intended to connote the inventive concept underlying the embodiments described below and not merely the embodiments themselves. It is to be understood further that the general inventive concept is not limited to the illustrative embodiments described below and the following descriptions should be read in such light.

Additionally, the word exemplary is used herein to mean, “serving as an example, instance or illustration.” Any embodiment of construction, process, design, technique, etc., designated herein as exemplary is not necessarily to be construed as preferred or advantageous over other such embodiments. Particular quality or fitness of the examples indicated herein as exemplary is neither intended nor should be inferred.

Mathematical expressions are contained herein and those principles conveyed thereby are to be taken as being thoroughly described therewith. It is to be understood that where mathematics are used, such is for succinct description of the underlying principles being explained and, unless otherwise expressed, no other purpose is implied or should be inferred. It will be clear from this disclosure overall how the mathematics herein pertain to the present invention and, where embodiment of the principles underlying the mathematical expressions is intended, the ordinarily skilled artisan will recognize numerous techniques to carry out physical manifestations of the principles being mathematically expressed.

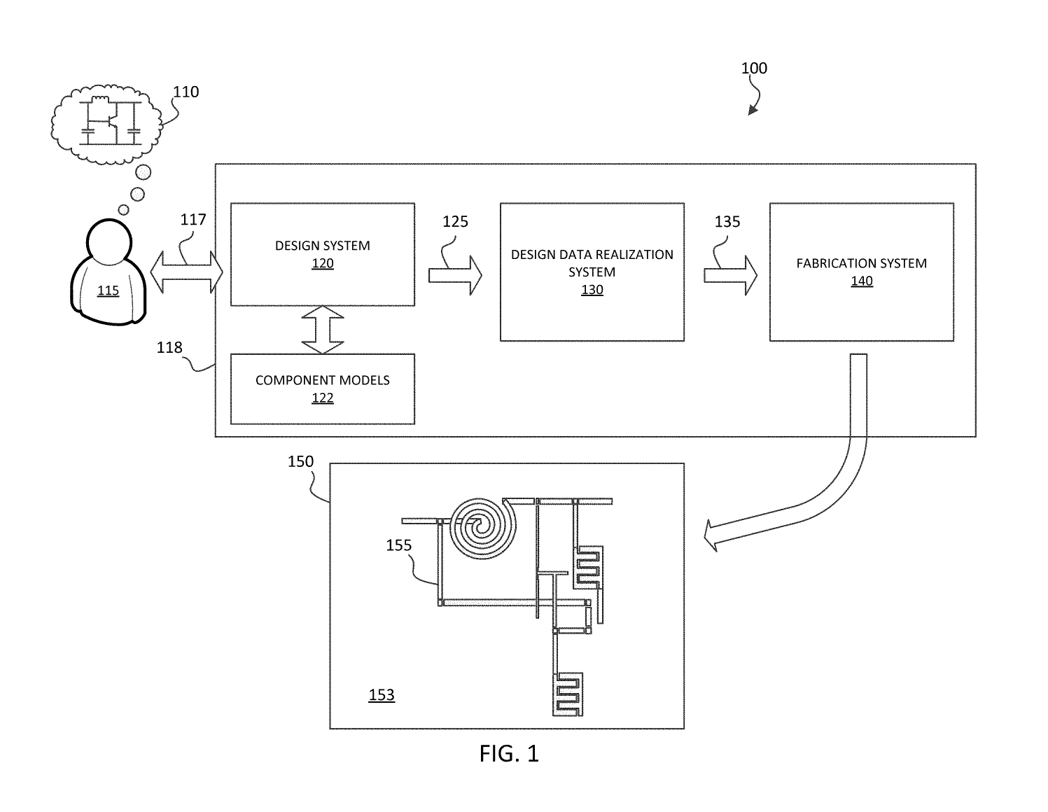

FIG. 1 illustrates a simplified depiction of an exemplary process 100 by which an electrical circuit 155 may be physically realized from a design concept. A circuit design typically starts as a concept 110 in the mind of the designer, or designers, represented by designer 115. The designer 115 may interact with a design system 120 to perform various design tasks, as illustrated at interactions 117. By way of the interactions 117 with design system 120, the designer may construct, simulate, modify, and verify design data 125 of a physical system 150 that may be ultimately used to fabricate or construct the physical system 150. The design system 120 may be a data processing apparatus executing processing instructions to perform computational, transformational and data presentation processes as directed by the designer 115.

As is illustrated in FIG. 1, the design data 125 may be provided to design data realization system 130, whereby the design data 125 may be processed into a tangible form by which the physical system 150 may be physically fabricated or constructed. The design data realization system 130 produces realization data 135 and provides the realization data to fabrication system 140 by which the physical system 150 is fabricated. The realization data 135 may include data formatted to physically fabricate, for example, circuit component structures 155 on one or more circuit-bearing media 153. Such realization data 135 may include data to construct component and interconnect mask patterns, component placement location data, packaging data, and any other data necessary in a fabrication process to produce the physical system 150, illustrated in FIG. 1 as finished circuit product 150.

As illustrated in FIG. 1, design system 100 may include one or more libraries of component models 122 by which the circuit under design may be simulated and performance characteristics evaluated before the circuit is fabricated or otherwise finalized. Those having skill in the art will recognize numerous such component models, which may include physical models, equivalent circuit models and behavioral models. Embodiments of the present invention realize such a behavioral model of a concurrent multiband amplifier.

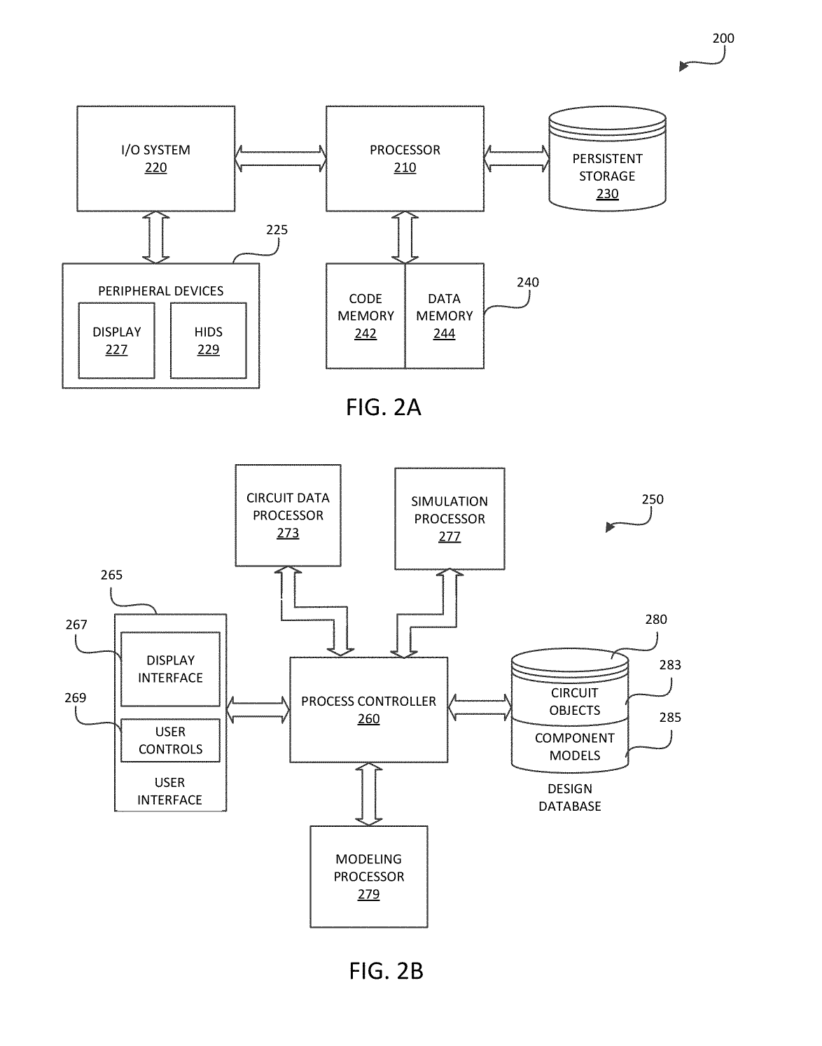

FIG. 2A illustrates an exemplary machine configuration suitable to practice the present invention. An exemplary data processing apparatus 200 of FIG. 2A includes an input/output (I/O) system 220, through which the data processing apparatus 200 may communicate with peripheral devices, collectively represented at block 225, and/or with external network devices (not illustrated). Among the peripheral devices 225 may be a display device 227, on which data are displayed as image data, and one or more Human Interface Devices (HIDs) 229, such as a keyboard, a mouse, a track ball, a stylus, a touch screen, a touchpad, and/or other devices suitable to provide input to the data processing apparatus 200.

The exemplary data processing apparatus 200 of the embodiment illustrated in FIG. 2A includes a processor 210 to, among other things, execute processing instructions that implement various functional modules, such as those described below with reference to FIG. 2B. It is to be understood that the present invention is not limited to a particular hardware configuration or instruction set architecture of the processor 210, which may be configured by numerous structures that perform equivalently to those illustrated and described herein. Moreover, it is to be understood that while the processor 210 is illustrated as a single component, certain embodiments of the invention may include distributed processing implementations through multiple processing elements. The present invention is intended to embrace all such alternative implementations, and others that will be apparent to the skilled artisan upon review of this disclosure.

A storage unit 240 may be utilized to store data and processing instructions on behalf of the exemplary data processing apparatus 210 of FIG. 2A. The storage unit 240 may include multiple segments, such as a code memory 242 to maintain processor instructions to be executed by the processor 210, and data memory 244 to store data, such as data structures on which the processor 210 performs data manipulation operations. The storage unit 240 may include memory that is distributed across components, to include, among others, a cache memory and a pipeline memory.

The data processing apparatus 200 may include a persistent storage system 230 to store data and processing instructions across processing sessions. The persistent storage system 230 may be implemented in a single persistent memory device, such as a hard disk drive, or may be implemented in multiple persistent memory devices, which may be interconnected by a communication network.

FIG. 2B illustrates an exemplary configuration of functional modules suitable to practice certain embodiments of the present invention. The exemplary system illustrated in FIG. 2B may be implemented through processing instructions executed on the processor 210, and in cooperation with other components as illustrated in FIG. 2A, form an exemplary circuit design system (CDS) 250 on the exemplary data processing apparatus 200. The exemplary CDS 250 may be operated by a circuit designer to design and analyze circuit designs and to provide circuit realization data upon affirmation that the circuit design is compliant with predefined design rules. The design system 120 of FIG. 1 may be implemented by the exemplary CDS 250.

It is to be understood that the number and respective assignment of functions to the functional modules illustrated in FIG. 2B has been chosen as a matter of convenience for facilitating a complete description of the exemplary embodiment illustrated therein. Additionally, certain embodiments of CDS 250 will include functional modules other than those illustrated, but such additional functional modules have been omitted in the interest of conciseness. The skilled artisan will recognize numerous other configurations and functional groupings to carry out the present invention. The scope of the present invention is intended to embrace all such alternative configurations.

The exemplary CDS 250 includes a process controller 260 to coordinate and control the interoperations of the functional modules of the CDS 250 so as to achieve a fully operational data processing system. For example, the process controller 260 may receive data corresponding to user manipulations of the user interface 265, may format the data into a command and/or data location in memory, and may convey such information to the applicable functional module of the CDS 250. The process controller 260 may subsequently receive processed data from the applicable functional module and forward the data to another functional module, as well as to indicate such processing on the user interface 265. The process controller 260 will perform other coordination and control operations according to the implementation of the CDS 250, and such other operations, as well as the implementation thereof, can be embodied by a wide range of well-known process control methods and apparatuses. The present invention is intended to encompass all such alternatives of the process controller 260, including multi-threaded and distributed process control methodologies.

As indicated above, the CDS 250 may include a user interface 265 through which a user interacts with the CDS 250. The user interface 265 may be implemented by a combination of hardware devices and suitably programmed processing instructions executed by the processor 210. The user interface 265 may be used to present data to the user in a meaningful form on a display interface 267, such as through graphical representations of circuit schematics, circuit layout diagrams, circuit test bench interfaces, and of data management interfaces such as file directories, circuit hierarchy diagrams, and other images recognized by the user. The user interface 265 may interpret user manipulations of any HIDs thereof into signals, messages and instructions that can be recognized by the process controller 260. The user interface 265 may include a plurality of user controls 269 to afford the user interactivity with and control over the CDS 250. The user controls 269 may include the HIDs described above, and may also include software implemented controls on the display interface 267, such as toolbars and/or buttons, menus of commands, text command entry blocks, and other suitable software controls. The foregoing description of the user interface 265 may be met by a suitably configured graphical user interface (GUI), the implementation details of such will be omitted in the interest of conciseness.

The CDS 250 may include a design database 280 of circuit objects 283 that maintain all the data necessary to design, analyze, modify, and fabricate an electric circuit per the specifications of a circuit designer. As used herein, a circuit object is a data structure that can be stored in a memory device to contain data of a circuit element so that the circuit element can be viewed, modified, logically connected with other circuit elements, and analyzed in one or more circuit design contexts selected by a user. A circuit object may also contain graphical abstraction information so that a particular circuit element may be presented on the display interface 267 as, for example, a schematic symbol in a schematic entry design context. A circuit object may also be hierarchical, whereby a circuit object contains other circuit objects of circuit elements interconnected to form a component that has a schematic symbol, layout footprint, and a terminal characteristics model used as a single element in a circuit.

Circuit objects 283 may include component models 285 that simulate respective electric circuit components in a circuit design or analysis setting. A component model, as the term is used herein, is a specification of terminal characteristics of the electrical component being modeled. A component model may be embodied by a set of processor instructions executable under processing resources of a particular framework, such as an electronic design automation (EDA) system like CDS 250. In certain embodiments, a component model for a power amplifier circuit object may be embodied as a set of multiplicative factors (coefficients) and set of processor instructions compelling a processor to apply the multiplicative factors in a certain way to the input signal (and delayed versions of the input signal) to produce a corresponding output. Component models may be characterized by their size (e.g., number of coefficients) and speed (simulation time).

CDS 250 may include a circuit data processor 273 by which circuit designs are constructed from circuit objects 283. Typically, a circuit designer forms a representation of a circuit through user interface 265 and circuit data processor 273 may form a corresponding circuit model from circuit objects 283 and component models 285. Simulation processor 277 may perform circuit simulations based on individual and collective behavior of circuit components represented in the circuit design. Such simulations may be realized and constrained by terminal characteristics specified by component models 285.

CDS 250 may further include a modeling processor 279 by which new component models may be constructed or otherwise configured. For example, modeling processor 279 may determine coefficients of a memory polynomial in accordance with the principles described herein.

For a dual band model, each communication band composed of one cell can be defined using the general memoryless model:

$$y ( n ) = {\sum }_{k = 1}^{N} {a}_{k} {x}^{k} ( n )$$

where aₖ is the set of model coefficients, y(n) is the model output and x(n) is the input.

A nonlinear behavior of a multi-band PA can be modeled by the 7th memory polynomial model. Generally, in multi-band mode, the equivalent input signal with frequency separation Δ ω=|ω₂−ω₁| can be given by:

x(n)=x₁(n)e^{jω}^{₁}^{nT}^{ₛ}+x₂(n)e^{jω}^{₂}^{nT}^{ₛ}

where ω₁ and ω₂ are the carrier frequencies, x₁(n) and x₂(n) are the complex envelopes of each band and T_{S} is the sampling time T_{S}=1/f_{S}, where f_{S} is the sampling frequency.
A relation between the output signal in each band to the two input signals may be given by:

y(n)=A₁x(n)+A₃x(n)|x(n)|²+A₅x(n)|x(n)|⁴+A₇x(n)|x(n)|⁶

where x(n) and y(n) are the input and output baseband signal and Aₖ (k=1, 3, 5, 7) are the model coefficients. Then, the nonlinear behavioral model can be derived by taking into account the terms around the two center frequencies (including in-band intermodulation and cross-band intermodulation products) to produce a two dimensional model in the form of:

y₁(n)=Σₘ₌₀^{M}Σₖ₌₁^{N}Σᵣ_{₁}₌₀^{k-1}Σᵣ_{₂}₌₀^{k-r}^{₁}⁻¹A_{k,r}_{₁}_{,r}_{₂}⁽¹⁾x₁(n−m)|x₁(n−m)|^{2r}^{₁}|x₂(n−m)|^{2r}^{₂} (1)

y₂(n)=Σₘ₌₀^{M}Σₖ₌₁^{N}Σᵣ_{₁}₌₀^{k-1}Σᵣ_{₂}₌₀^{k-r}^{₁}⁻¹A_{k,r}_{₁}_{,r}_{₂}⁽²⁾x₂(n−m)|x₁(n−m)|^{2r}^{₁}|x₂(n−m)|^{2r}^{₂} (2)

where A_{k,r}_{₁}_{,r}_{₂}⁽¹⁾ and A_{k,r}_{₁}_{,r}_{₂}⁽²⁾ are the model coefficients, M is the memory depth and N is the non-linearity order. In this model, M is 7.

Coefficients A_{k,r}_{₁}_{,r}_{₂}⁽¹⁾ and A_{k,r}_{₁}_{,r}_{₂}⁽²⁾ may be assigned the following values:

$${A}_{k , {r}_{1} , {r}_{2}}^{( 1 )} = \frac{1}{{2}^{k - 1}} {a}_{k , {r}_{1} , {r}_{2}}^{( 1 )} {C}_{{r}_{1}}^{k} {C}_{{r}_{2}}^{k - {r}_{1}} , \\ {A}_{k , {r}_{1} , {r}_{2}}^{( 2 )} = \frac{1}{{2}^{k - 1}} {a}_{k , {r}_{1} , {r}_{2}}^{( 2 )} {C}_{{r}_{1}}^{k} {C}_{{r}_{2}}^{k - {r}_{1}} , where$$

$${C}_{b}^{a} = \frac{a !}{b ! ( a - b ) !} ,$$

and a_{k,r}_{₁}_{,r}_{₂}⁽¹⁾ and a_{k,r}_{₁}_{,r}_{₂}⁽²⁾ are coefficients or weights that control the contribution of constituent polynomial terms of equations (1) and (2) and hence control the terminal characteristics of the power amplifier circuit object. Here, r₁ and r₂ represent the index of the model coefficients according to k (such as a_{k,0,0}⁽¹⁾) or a_{k,2,3}⁽²⁾).

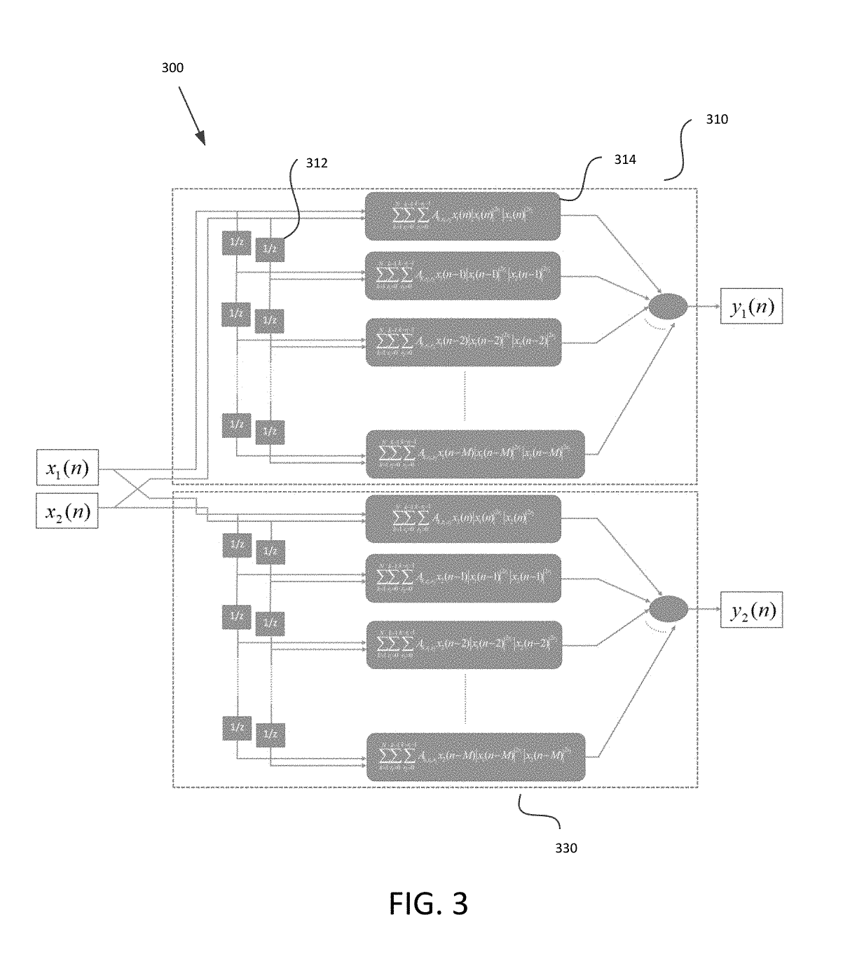

FIG. 3 is a schematic block diagram of a memory polynomial-based behavioral model 300 of a dual-band power amplifier in accordance with an exemplary aspect of the disclosure. Model 300 comprises a processing block 310 for generating output signal y₁(n) from input signals x₁(n) and x₂(n) and a processing block 330 for generating output signal y₂(n) from input signals x₁(n) and x₂(n). As illustrated in the figure, each processing block 310 and 330 may be structured with delay components, representatively illustrated at delay component 312, to delay the input samples and implement the outer summation over M. It should be noted that the coefficients A_{k,r}_{₁}_{,r}_{₂}⁽¹⁾ and A_{k,r}_{₁}_{,r}_{₂}⁽²⁾ are not indexed over m, which manifests as a reduction in the number of coefficients that must be implemented, which decreases storage requirements and improves the operation of CDS 250 with respect to simulation time and model complexity.

Processing blocks 310 and 320 each may also comprise a set of polynomial processing blocks 314 that perform the inner summations and multiplications to calculate the polynomials of equations (1) and (2). It is to be noted that the nonlinear terms are confined to even orders. One benefit of operating on even-order nonlinear terms is increased modeling accuracy and reduction of modeling errors. Moreover, it allows the use of lower order polynomials, which have better numerical properties.

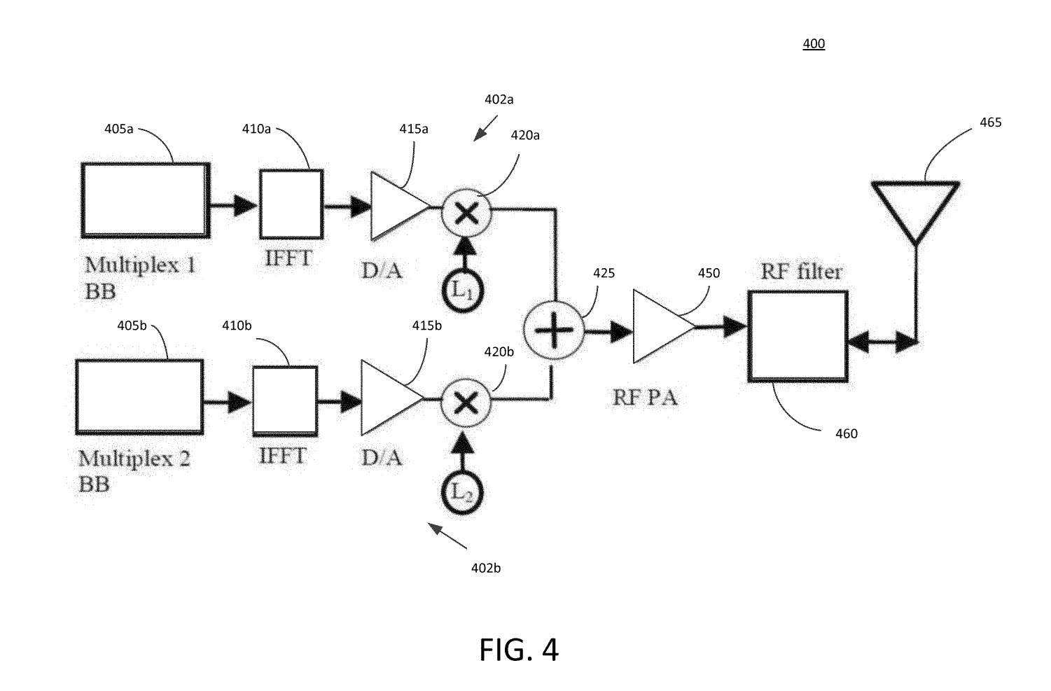

FIG. 4 is a schematic circuit diagram depicting an exemplary concurrent dual-band transmitter 400 that may be designed and analyzed through embodiments of the present invention. Each of the components illustrated in FIG. 4 may be realized by a corresponding component model for purposes of design and analysis of the overall circuit.

As illustrated in FIG. 4, concurrent dual-band transmitter 400 includes a pair of signal processing chains 402a and 402b by which input signals x₁(n) and x₂(n) are processed for transmission. Each processing chain 402a and 402b may include respective baseband multiplexer circuits 405a and 405b, inverse fast Fourier transform circuits 410a and 410b, digital to analog conversion circuits 415a and 415b and upconverter circuits 420a and 420b. Processing chains 402a and 402b may be mutually terminated in a power combiner 425 by which the upconverted signals carrying x₁(n) and x₂(n) are combined and provided to power amplifier 450 for concurrent amplification. The amplified signal may be provided to an RF filter 460 to remove out-of-band artifacts and then to an antenna 465 by which the amplified signal is radiated into free space.

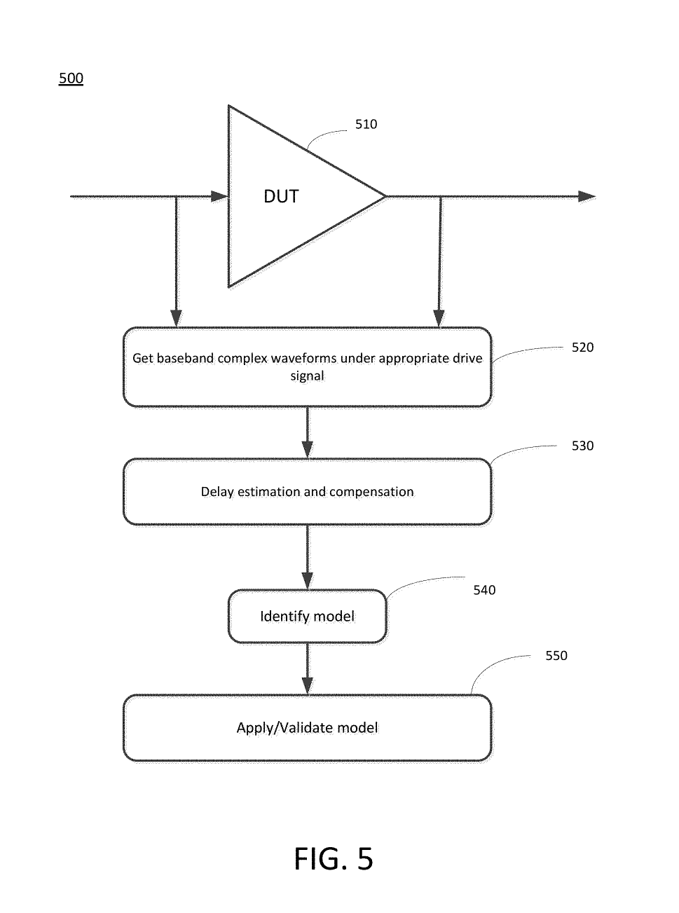

FIG. 5 is a schematic block diagram of a design process 500 by which the present invention can be embodied. The goal of design process 500 is to configure a behavioral model to simulate a device under test (DUT) 510, such as a concurrent multiband power amplifier. In operation 520, the baseband complex waveforms are acquired under an appropriate drive signal, such as those conforming to LTE telecommunication standards. In operation 530, delay estimation and compensation are performed. In operation 540, the model is identified and, in operation 550, the model is applied and validated.

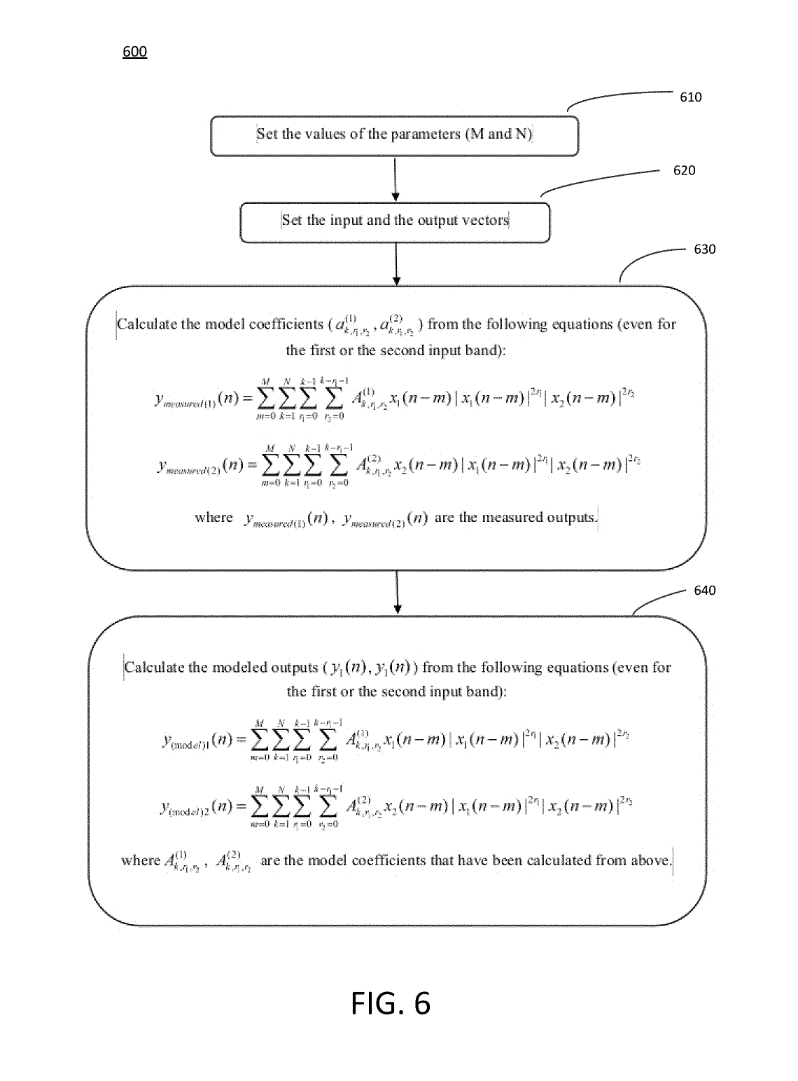

FIG. 6 is a flow diagram of a model identification process 600 that can be used in conjunction with embodiments of the present invention. In operation 610, the values for the memory depth M and non-linearity order N are set. In operation 620, the input and output vectors are set. The vectors are 2-dimensional vectors with IQ (In-phase and Quadrature) values that represent the complex signal form for each input and output set (I+Qi) which have been collected experimentally. In operation 630, measurements are made and such measurements are equated to equations (1) and (2) to determine the model coefficients a_{k,r}_{₁}_{,r}_{₂}⁽¹⁾ and a_{k,r}_{₁}_{,r}_{₂}⁽²⁾. In operation 640, using the model coefficients a_{k,r}_{₁}_{,r}_{₂}⁽¹⁾ and a_{k,r}_{₁}_{,r}_{₂}⁽²⁾ from operation 630, equations (1) and (2) are evaluated to determine y_{model1}(n) and y_{model2}(n), i.e., the model output using the captured model coefficients.

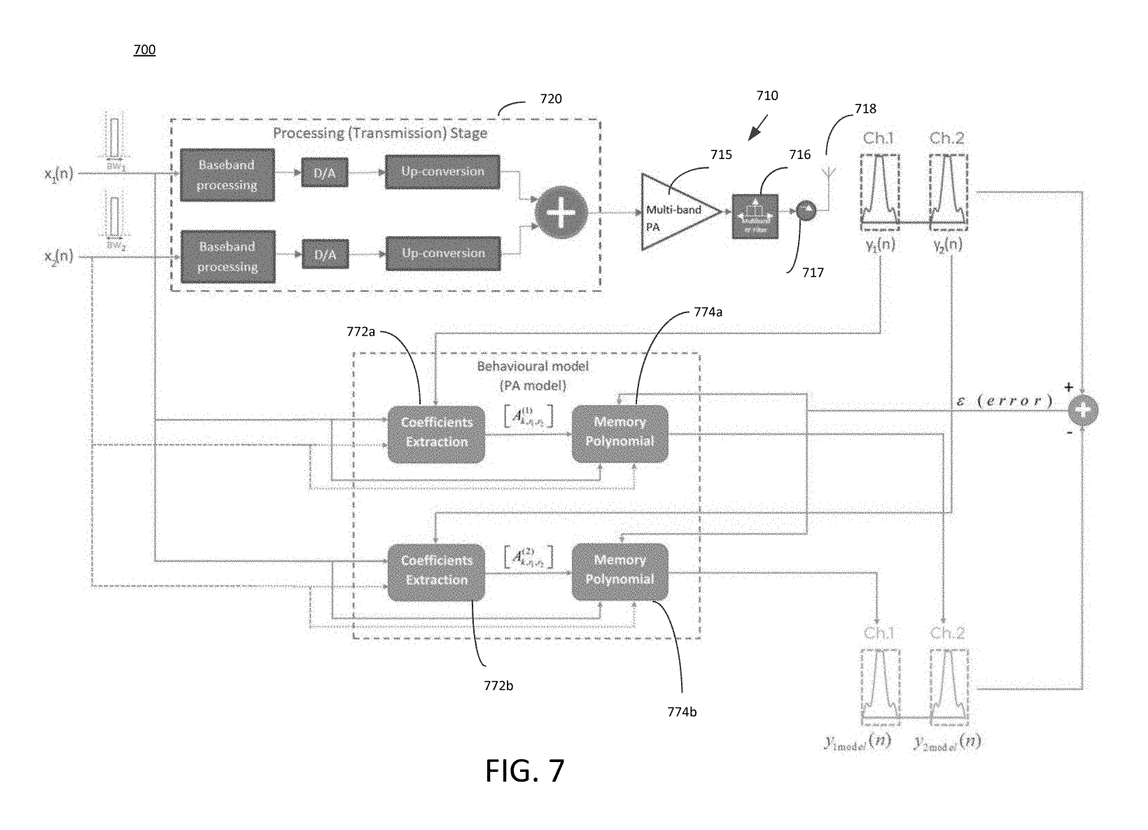

FIG. 7 is a schematic block diagram of an example system 700 by which a behavioral model 770 embodying the invention is configured for a specific power amplifier 715. A properly configured behavioral model may be used to simulate that specific amplifier in applicable circuit design systems. As illustrated in FIG. 7, example system 700 includes an amplifier circuit 710 similar in construction and operation as that described above in FIG. 4. Amplifier circuit 710 may include a processing stage 720 by which input signals x₁(n) and x₂(n) are processed for transmission, a multiband power amplifier 715 for which a behavioral model according to equations (1) and (2) is constructed, a bandpass filter 716 to filter out-of-band signals, a circulator 717 and an antenna 718. It is to be understood that amplifier circuit 710 may be a circuit design in an EDA system, such as CDS 250.

System 700 includes a behavioral model 770 that may be configured based on measurements of the output of antenna 718, i.e., y₁(n) and y₂(n). As illustrated in FIG. 7, behavioral model 770 may include coefficient extraction components 772a and 772b by which coefficients A_{k,r}_{₁}_{,r}_{₂}⁽¹⁾ and A_{k,r}_{₁}_{,r}_{₂}⁽²⁾ are determined given the inputs x₁(n) and x₂(n), and outputs y₁(n) and y₂(n). Behavioral model 770 may further include memory polynomials 774a and 774b, such as those of equations (1) and (2). Given the coefficients A_{k,r}_{₁}_{,r}_{₂}⁽¹⁾ and A_{k,r}_{₁}_{,r}_{₂}⁽²⁾ extracted by coefficient extraction components 772a and 772b, and an error signal representing a difference between the current outputs y₁(n) and y₂(n) and previously modeled outputs y_{1model}(n) and y_{2model}(n), coefficients A_{k,r}_{₁}_{,r}_{₂}⁽¹⁾ and A_{k,r}_{₁}_{,r}_{₂}⁽²⁾ may be updated so as to minimize the error signal.

The present disclosure has been implemented in a concurrent dual-band transmitter design simulating operation on LTE compliant signals. The power amplifier in this implementation is a highly nonlinear class AB GaN power amplifier in a long term evolution (LTE) signal environment with different carrier configurations. The output power gain is approximately 10 W. The operating frequency for the bands are between 2.4-2.5 GHz and the sampling frequency is 15.36 MHz for the LTE carrier signal.

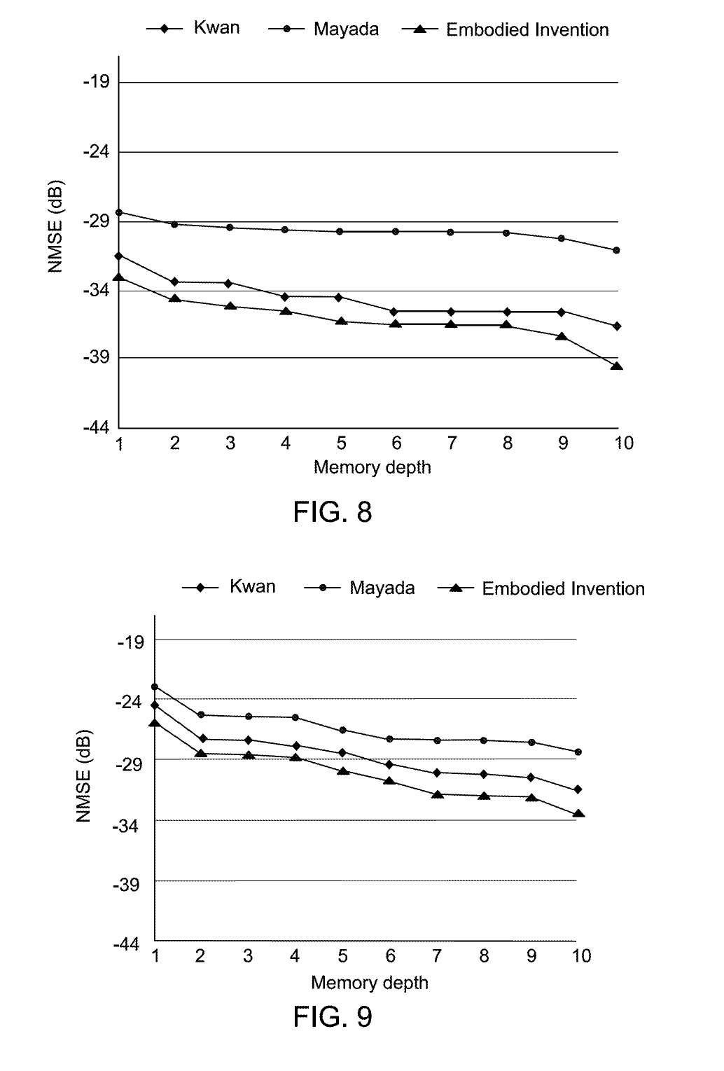

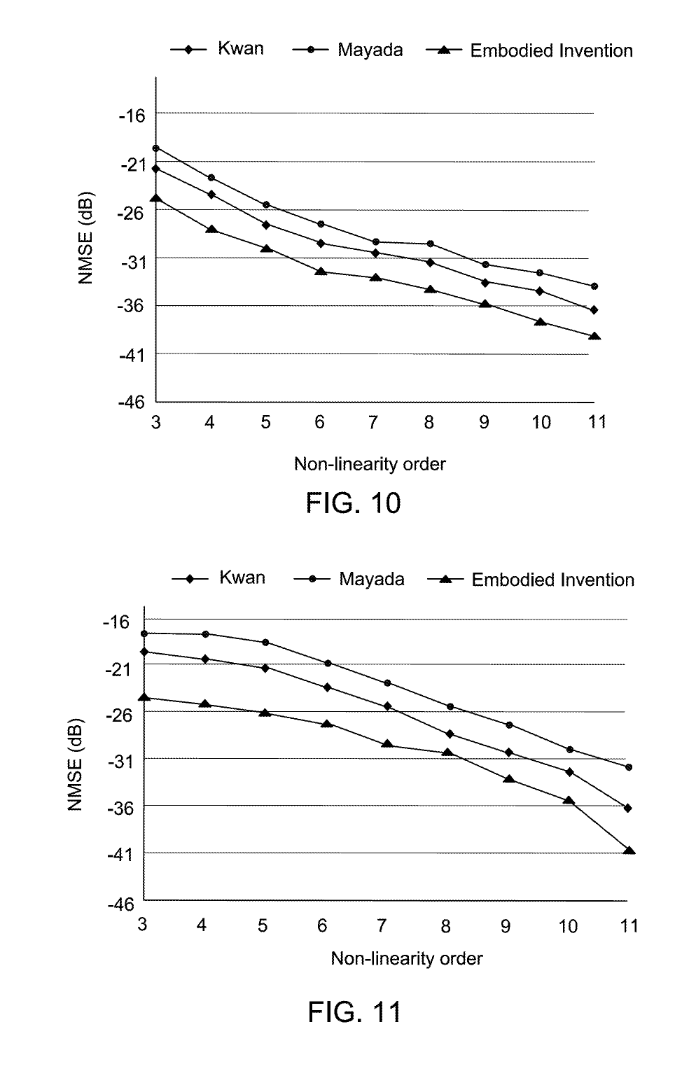

FIGS. 8, 9, 10 and 11 illustrate normalized mean square error (NMSE) performance for various amplifier models, i.e., the model of Kwan versus the model of Mayada verses the behavioral model embodiment of the present invention. In FIG. 8 and FIG. 9, the nonlinearity order (N) was 5 and the memory depth (M) was varied between 1 and 10 for the low and high data bands, respectively. In FIG. 10 and FIG. 11, the memory depth (M) was held constant at 3 as the nonlinearity order (N) was varied between 3 and 11 for the high and low data bands, respectively. The model in Mayada gave the worst NMSE performance compared to the one in Kwan and the present embodiment. On the other hand, the example embodiment shows a competition against Kwan's model in terms of having less NMSE in both the low and the high band of the LTE signals. It can be seen that the performance of the example embodiment can be better than the one in Kwan for both low and high bands.

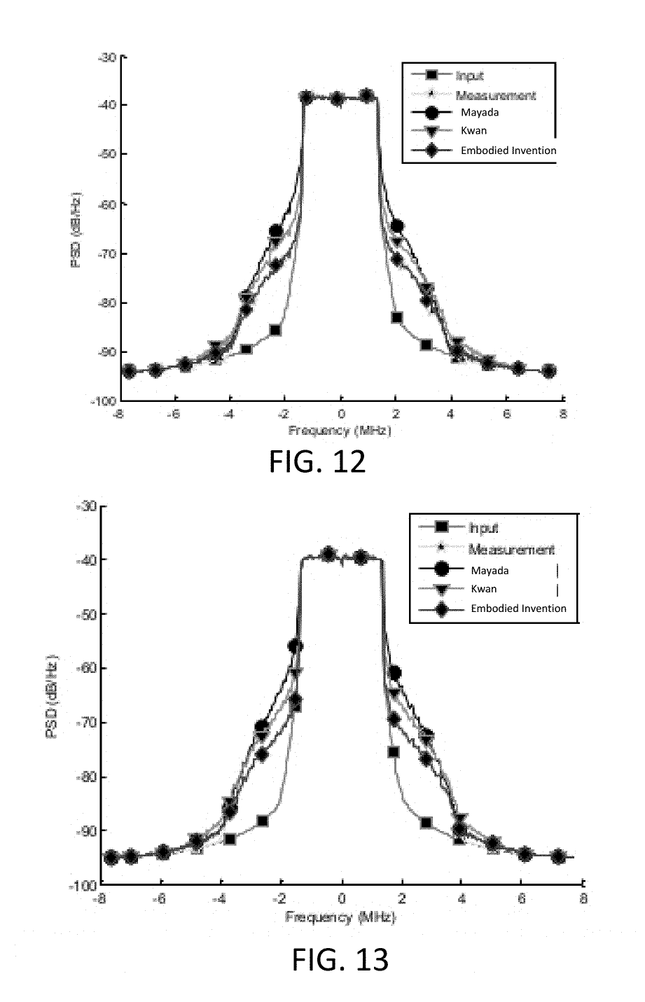

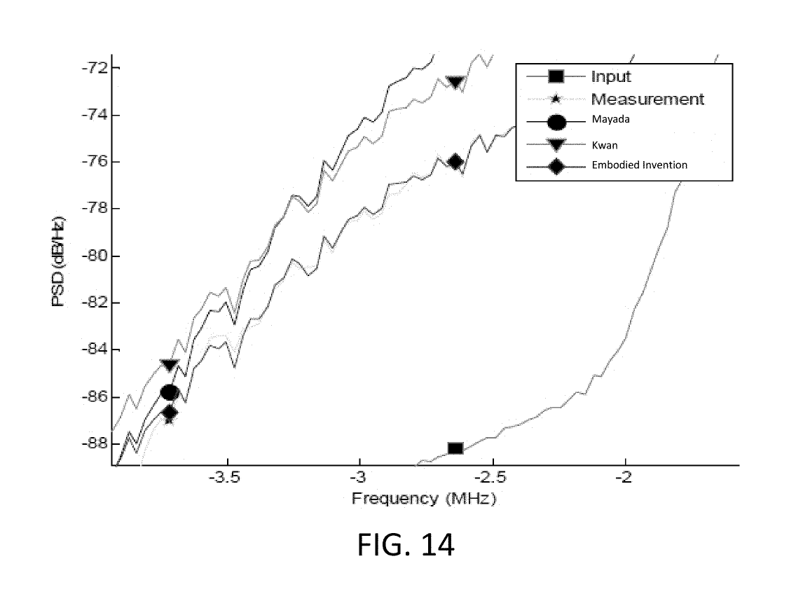

FIG. 12 and FIG. 13 give the output spectrum of the comparison MP models to illustrate which model gives the spectrum closest to the measurement output of the PA. In FIG. 12, it appears that the low band output spectrum for the model in Mayada gives the highest nonlinearity while the model in Kwan with the proposed model gives a close shape to the measurement output as appear in FIG. 12. The same goes to the high band in FIG. 13, where the embodiment of the invention is more similar to the measurement output signal than both models in Kwan and Mayada which give a linearity worse than the measurement output as appear in FIG. 13. FIG. 14 is an expanded view of the output spectrum demonstrating the close adherence of the embodied invention to the measured spectrum.

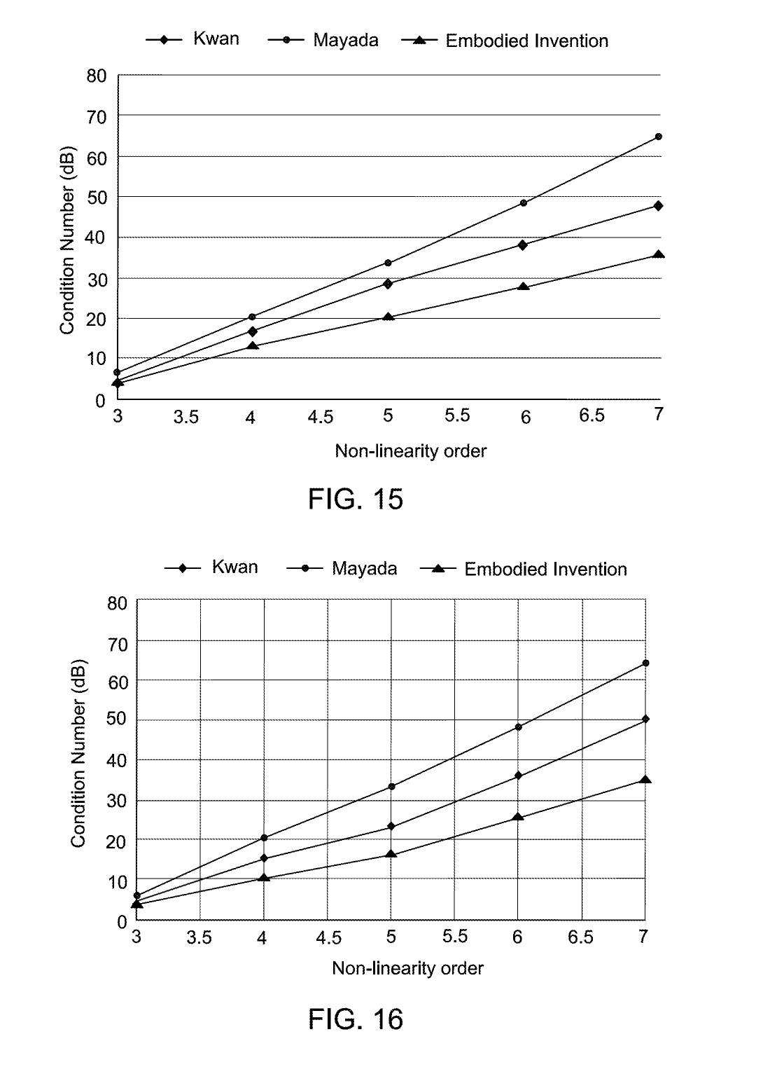

In FIG. 15 and FIG. 16, the output of the models is expressed in terms of its condition number metrics as a function of nonlinearity order N in addition to a constant memory depth (M=3). The value of N was driven experimentally for values swept between 3 and 11. In FIG. 15 and FIG. 16, the selected value provides satisfactory modelling accuracy for the proposed models against the earlier MP models (Kwan and Mayada) in both the low and the high data bands. Here, it can be seen that the condition number of the proposed model is significant, which result in having better performance with the dual-band MP model for PAs behavioral modeling.

A thorough comparison of the performances of the embodied invention and the conventional models for the cases of the considered test signals is presented in Table 1 by taking a sample of the output with a memory depth (M=3) and nonlinearity order (N=5).

TABLE 1

| | MP Model in | MP Model in | Embodied |
|---|---|---|---|
| | Mayada | Kwan | Invention |
| Number of Coefficients | 3476 | 1084 | 684 |

Low Band (a)

| (M, N) | (3, 5) | | |
|---|---|---|---|
| NMSE (dB) vs. M | −29.42 | −33.41 | −35.13 |
| NMSE (dB) vs. N | −25.43 | −27.45 | −29.94 |
| Condition Number (dB) | 33.70 | 28.58 | 20.20 |

High Band (b)

| (M, N) | (3, 5) | | |
|---|---|---|---|
| NMSE (dB) vs. M | −26.54 | −28.40 | −29.96 |
| NMSE (dB) vs. N | −18.61 | −21.40 | −26.10 |
| Condition Number (dB) | 33.47 | 23.23 | 16.29 |

The table shows the difference in NMSE between the embodied invention and the conventional models in Kwan and Mayada for the high and low data band signals. The present invention embodiment improves the conditioning number metrics by up to 13 dB (approximately 18.4%) as compared to the best of the conventional models which are due to the substantial decrease in the number of coefficients. Furthermore, the total number of coefficients is decreased by almost 33.5% in the considered cases.

The results show that embodiments of the present disclosure can realize improvements in performance over those described in Kwan and Mayada in both the high and the low bands ((a) and (b)). Embodiments of the invention promise results with high minimizing the memory effects and distortion even in high values of memory depth and nonlinearity order which lead to having almost the same measurement output spectrum.

Based on choosing the accurate model dimensions for a trade-off between the model accuracy (evaluated in terms of NMSE), model robustness (evaluated in terms of conditioning number), and the model complexity (evaluated in terms of a total number of coefficients) which demonstrate in a tolerance percentage. The results show that the proposed dual-band memory polynomial models led to a good comparable performance in the time domain and frequency domain in addition to having lower computational complexity.

The storage areas and memory may be implemented by any quantity of any type of conventional or other memory or storage device, and may be volatile (e.g., RAM, cache, flash, etc.), or non-volatile (e.g., ROM, hard-disk, optical storage, etc.), and include any suitable storage capacity. The storage areas may be, for example, one or more databases implemented on a solid state drive or in a RAM cloud.

The processor is, for example, one or more data processing devices such as microprocessors, microcontrollers, systems on a chip (SOCs), or other fixed or programmable logic, that executes instructions for process logic stored the memory. The processors may themselves be multi-processors, and have multiple CPUs, multiple cores, multiple dies comprising multiple processors, etc.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable medium may be, for example, but is not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a solid state disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, a phase change memory storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, e.g., an object oriented programming language such as Java, Smalltalk, C++ or the like, or a conventional procedural programming language, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

It is to be understood that the software for the computer systems of the present invention embodiments may be implemented in any desired computer language and could be developed by one of ordinary skill in the computer arts based on the functional descriptions contained in the specification and flow charts illustrated in the drawings. By way of example only, the software may be implemented in the C++, Java, P1/1, Fortran or other programming languages. Further, any references herein of software performing various functions generally refer to computer systems or processors performing those functions under software control.

The computer systems of the present invention embodiments may alternatively be implemented by any type of hardware and/or other processing circuitry. The various functions of the computer systems may be distributed in any manner among any quantity of software modules or units, processing or computer systems and/or circuitry, where the computer or processing systems may be disposed locally or remotely of each other and communicate via any suitable communications medium (e.g., LAN, WAN, Intranet, Internet, hardwire, modem connection, wireless, etc.).

Aspects of the present invention are described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A processing system suitable for storing and/or executing program code may be implemented by any conventional or other computer or processing systems preferably equipped with a display or monitor, a base (e.g., including the processor, memories and/or internal or external communications devices (e.g., modem, network cards, etc.) and optional input devices (e.g., a keyboard, mouse or other input device)). The system can include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution. Input/output or I/O devices (including but not limited to keyboards, displays, pointing devices, etc.) can be coupled to the system either directly or through intervening I/O controllers. Network adapters may also be coupled to the system to enable the system to become coupled to other processing systems or remote printers or storage devices through intervening private or public networks. Modems, cable modem and Ethernet cards are just a few of the currently available types of network adapters.

The flowchart and block diagrams in the Figures illustrate the architecture, functionality, and operation of possible implementations of systems, method and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometime be executed in the reverse order, depending on the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The descriptions above are intended to illustrate possible implementations of the present inventive concept and are not restrictive. Many variations, modifications and alternatives will become apparent to the skilled artisan upon review of this disclosure. For example, components equivalent to those shown and described may be substituted therefore, elements and methods individually described may be combined, and elements described as discrete may be distributed across many components. The scope of the invention should therefore be determined not with reference to the description above, but with reference to the appended claims, along with their full range of equivalents.

1. An apparatus for behavioral modeling of a concurrent multiband amplifier comprising:
a memory to store coefficients of a memory polynomial having summations over no more than four indices including memory order and nonlinearity order, and nonlinear terms confined to even powers; and
a processor circuitry that executes a model of the multiband amplifier according to the memory polynomial.

2. The apparatus of claim 1, wherein coefficients of the memory polynomial are indexed over no more than three of the four indices.

3. The apparatus of claim 2, wherein the indices that the coefficients are not indexed over includes the memory order index.

4. The apparatus of claim 2, wherein the memory polynomial is a 2-dimensional memory polynomial.

5. The apparatus of claim 4, wherein the memory polynomial is given by:
$${y}_{1} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 1 )} {x}_{1} ( n - m ) {\vert {x}_{1} ( n - m ) \vert}^{2 {r}_{1}} {\vert {x}_{2} ( n - m ) \vert}^{2 {r}_{2}}$$
$${y}_{2} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 2 )} {x}_{2} ( n - m ) {\vert {x}_{1} ( n - m ) \vert}^{2 {r}_{1}} {\vert {x}_{2} ( n - m ) \vert}^{2 {r}_{2}}$$
wherein M is memory depth and N is nonlinearity order.

6. A method for behavioral modeling of a concurrent multiband amplifier comprising:
storing coefficients of a memory polynomial having summations over no more than four indices including memory order and nonlinearity order, and nonlinear terms confined to even powers; and
executing a model of the multiband amplifier according to the memory polynomial.

7. The method of claim 6, wherein coefficients of the memory polynomial are indexed over no more than three of the four indices.

8. The method of claim 7, wherein the indices that the coefficients are not indexed over includes the memory order index.

9. The method of claim 7, wherein the memory polynomial is a 2-dimensional memory polynomial.

10. The method of claim 9, wherein the memory polynomial is given by:
$${y}_{1} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 1 )} {x}_{1} ( n - m ) {\vert {x}_{1} ( n - m ) \vert}^{2 {r}_{1}} {\vert {x}_{2} ( n - m ) \vert}^{2 {r}_{2}}$$
$${y}_{2} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 2 )} {x}_{2} ( n - m ) {\vert {x}_{1} ( n - m ) \vert}^{2 {r}_{1}} {\vert {x}_{2} ( n - m ) \vert}^{2 {r}_{2}}$$
wherein M is memory depth and N is nonlinearity order.

11. A non-transitory computer readable storage medium storing a program therein, which when executed by a computer performs a method for behavioral modeling of a concurrent multiband amplifier, the method comprising:
storing coefficients of a memory polynomial having summations over no more than four indices including memory order and nonlinearity order, and nonlinear terms confined to even powers; and
executing a model of the multiband amplifier according to the memory polynomial.

12. The non-transitory computer readable storage medium of claim 11, wherein coefficients of the memory polynomial are indexed over no more than three of the four indices.

13. The non-transitory computer readable storage medium of claim 12, wherein the indices that the coefficients are not indexed over includes the memory order index.

14. The non-transitory computer readable storage medium of claim 12, wherein the memory polynomial is a 2-dimensional memory polynomial.

15. The non-transitory computer readable storage medium of claim 14, wherein the memory polynomial is given by:
$${y}_{1} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 1 )} {x}_{1} ( n - m ) {\vert {x}_{1} ( n - m ) \vert}^{2 {r}_{1}} {\vert {x}_{2} ( n - m ) \vert}^{2 {r}_{2}}$$
$${y}_{2} ( n ) = {\sum }_{m = 0}^{M} {\sum }_{k = 1}^{N} {\sum }_{{r}_{1} = 0}^{k - 1} {\sum }_{{r}_{2} = 0}^{k - {r}_{1} - 1} {A}_{k , {r}_{1} , {r}_{2}}^{( 2 )} {x}_{2} ( n - m ) {\vert {x}_{1} ( n - m ) \vert}^{2 {r}_{1}} {\vert {x}_{2} ( n - m ) \vert}^{2 {r}_{2}}$$
wherein M is memory depth and N is nonlinearity order.
